(19) United States
(12) Patent Application Publication
(10) Pub. No.: US 2026/0173903 A1
(43) Pub. Date: Jun. 18, 2026

(54) LANDLESS WIDE VIA STRUCTURES FOR HIGH DENSITY INTERCONNECT

(71) Applicant: International Business Machines Corporation, Armonk, NY (US)

(72) Inventors: Toyohiro Aoki, Yokohama (JP); Hiroyuki Mori, Yasu-shi (JP); Akihiro Horibe, Yokohama (JP); Takahito Watanabe, Yokohama (JP)

(21) Appl. No.: 18/981,364

(22) Filed: Dec. 13, 2024

(51) Int. Cl. H01L 23/00

(52) U.S. Cl. CPC H10W 70/60; H10W 70/09; H10W 70/65

(57) ABSTRACT

An interconnect structure includes a substrate; and a first layer including a first layer wiring level outward of the substrate, a first layer landless via outward of the first layer wiring level, and a first layer wide via outward of the first layer landless via. A second layer includes a second layer wiring level outward of the first layer wide via, a second layer landless via outward of the second layer wiring level, and a second layer wide via outward of the second layer landless via. The wide vias are wider than the landless vias. A dielectric coating fills voids between the substrate, the first layer wiring level, the first layer landless via, the first layer wide via, the second layer wiring level, the second layer landless via, and the second layer wide via.

### BACKGROUND

The present invention relates generally to semiconductor devices, and more specifically, to semiconductor interconnect structures.

Silicon (Si) interposers are currently employed for high-end applications. Interposers with high density wiring are considered pertinent to achieving chiplet packaging. Interposers with a redistribution layer (RDL) (including Copper (Cu) wiring and an organic dielectric) is another conventional option that potentially improves electrical performance compared with Si interposers. One of the challenges for the organic RDL is wiring density where the wiring density depends on a line/space capability as well as via land size.

### BRIEF SUMMARY

Principles of the invention provide techniques for landless wide via structures for high density interconnects. In one aspect, an exemplary interconnect structure includes a substrate; and a first layer including a first layer wiring level outward of the substrate, a first layer landless via outward of the first layer wiring level, and a first layer wide via outward of the first layer landless via, the first layer wide via being wider than the first layer landless via. A second layer includes a second layer wiring level outward of the first layer wide via, a second layer landless via outward of the second layer wiring level, and a second layer wide via outward of the second layer landless via. The second layer wide via is wider than the second layer landless via. A dielectric coating fills voids between the substrate, the first layer wiring level, the first layer landless via, the first layer wide via, the second layer wiring level, the second layer landless via, and the second layer wide via.

In another aspect, an exemplary assembly includes: a first semiconductor build; a second semiconductor build; and an interconnect structure joining the first and second semiconductor builds. The interconnect structure includes: a substrate and a first layer including: a first layer wiring level outward of the substrate; a first layer landless via outward of the first layer wiring level; and a first layer wide via outward of the first layer landless via. The first layer wide via is wider than the first layer landless via. A second layer includes: a second layer wiring level outward of the first layer wide via; a second layer landless via outward of the second layer wiring level; and a second layer wide via outward of the second layer landless via. The second layer wide via is wider than the second layer landless via. A dielectric coating fills voids between the substrate, the first layer wiring level, the first layer landless via, the first layer wide via, the second layer wiring level, the second layer landless via, and the second layer wide via. The first and second semiconductor builds are electrically coupled using at least a portion of the first layer wiring level, the first layer landless via, the first layer wide via, the second layer wiring level, the second layer landless via, and the second layer wide via.

In still another aspect, another interconnect structure includes a substrate; and a first layer including: a first layer wiring level outward of the substrate; and a first layer landless via outward of the first layer wiring level. A second layer includes: a second layer wiring level outward of the first layer landless via; a second layer landless via outward of the second layer wiring level; and a second layer wide via outward of the second layer landless via. The second layer wide via is wider than the second layer landless via. A dielectric coating fills voids between the substrate, the first layer wiring level, the first layer landless via, the second layer wiring level, the second layer landless via, and the second layer wide via.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A illustrates cross-sections for example landless via structures, in accordance with example embodiments;

FIG. 1B is an example method for wiring layer fabrication, in accordance with example embodiments;

FIG. 2 illustrates detailed cross-sectional views of an example structure produced using the method of FIGS. 3A-3B, in accordance with example embodiments;

FIG. 3A shows a cross-sectional view for various steps of the process of FIG. 1B, in accordance with example embodiments;

FIG. 3B shows a top view for various steps of the process of FIG. 1B, in accordance with example embodiments;

FIG. 4 illustrates a detailed cross-sectional views of an example structure produced using the method of FIGS. 5A-5B, in accordance with example embodiments;

FIG. 5A shows a cross-sectional view for various steps of the process of FIG. 1B, in accordance with example embodiments;

FIG. 5B shows a top view for various steps of the process of FIG. 1B, in accordance with example embodiments;

FIG. 6A shows a cross-sectional view for various steps of the process of FIG. 1B, in accordance with example embodiments;

FIG. 6B shows a top view for various steps of the process of FIG. 1B, in accordance with example embodiments;

FIG. 7A illustrates detailed cross-sectional views of an example structure produced using the method of FIGS. 8A-8B, in accordance with example embodiments;

FIG. 7B illustrates an elongated pad (via) shape with a contact area that is increased compared with a cylinder via shape, in accordance with example embodiments;

FIG. 8A shows a cross-sectional view for various steps of the process of FIG. 1B, in accordance with example embodiments;

FIG. 8B shows a top view for various steps of the process of FIG. 1B, in accordance with example embodiments; and

FIG. 9 is a flowchart for the example method for wiring layer fabrication, in accordance with example embodiments.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), in aspects of the invention, an interconnect structure includes a substrate 328; and a first layer including: a first layer wiring level 336 outward of the substrate 328; a first layer landless via 340 outward of the first layer wiring level 336; and a first layer wide via 343 outward of the first layer landless via 340. The first layer wide via is wider than the first layer landless via. A second layer includes: a second layer wiring level 336 outward of the first layer wide via 343; a second layer landless via 340 outward of the second layer wiring level 336; and a second layer wide via 343 outward of the second layer landless via 340. The second layer wide via is wider than the second layer landless via. A dielectric coating 360 fills voids between the substrate 328, the first layer wiring level 336, the first layer landless via 340, the first layer wide via 343, the second layer wiring level 336, the second layer landless via 340, and the second layer wide via 343. Technical benefits include an interconnect structure that increases wiring density per unit length; an interconnect structure that can be fabricated without the need for a dry etch process when fabricating landless wide via structures; an interconnect structure that allows use of a wide range of dielectric materials; and the use of wide-vias at different levels (layers) than wiring levels (layers).

As an aside, it is worth noting that in one or more embodiments, the wide via is larger/wider than the corresponding landless via. The minimum diameter of the wide via can be determined considering lithography misalignment and size variation.

Some embodiments further include a seed layer 332 between the substrate 328 and the first layer wiring level 336. The seed layer deposition 332 can include, for example, Titanium (Ti) and Copper (Cu). Technical benefits include those discussed above with improved adhesion.

Some embodiments further include barrier metal 344 residing over the seed layer 332, the first layer wiring level 336, the first layer landless via 340, and the first layer wide via 343. The first barrier metal deposition 344 can include one of Nickel (Ni) and Cobalt (Co). Technical benefits include those discussed above with a barrier layer formed of readily available materials.

Some embodiments further include a third layer residing on the second layer; the third layer is configured in accordance with the first layer. Technical benefits include those discussed above while facilitating multiple wiring layers.

Some cases further include an outer Titanium and Copper deposition 348 residing on the second layer, an outer copper plating 352 residing on the outer Titanium and Copper deposition 348 and an outer barrier metal deposition 356 residing on the third copper plating 352. Technical benefits include those discussed above while facilitating connections to above structures.

In some cases, the first layer wide via 343 is entirely recessed within the first layer. Technical benefits include those discussed above while facilitating fabrication.

In another aspect, an exemplary assembly includes: a first semiconductor build 305, 505; a second semiconductor build 307, 507; and an interconnect structure joining the first and second semiconductor builds. The interconnect structure includes a substrate 328; and a first layer including: a first layer wiring level 336 outward of the substrate 328; a first layer landless via 340 outward of the first layer wiring level 336; and a first layer wide via 343 outward of the first layer landless via 340. The first layer wide via is wider than the first layer landless via. A second layer includes a second layer wiring level 336 outward of the first layer wide via 343; a second layer landless via 340 outward of the second layer wiring level 336; and a second layer wide via 343 outward of the second layer landless via 340. The second layer wide via is wider than the second layer landless via. A dielectric coating 360 fills voids between the substrate 328, the first layer wiring level 336, the first layer landless via 340, the first layer wide via 343, the second layer wiring level 336, the second layer landless via 340, and the second layer wide via 343. The first and second semiconductor builds are electrically coupled using at least a portion of the first layer wiring level, the first layer landless via, the first layer wide via, the second layer wiring level, the second layer landless via, and the second layer wide via. Technical benefits include an assembly with an interconnect structure that increases wiring density per unit length; an interconnect structure that can be fabricated without the need for a dry etch process when fabricating landless wide via structures; an interconnect structure that allows use of a wide range of dielectric materials; and the use of wide-vias at different levels (layers) than wiring levels (layers).

Some embodiments further include a seed layer 332 between the substrate 328 and the first layer wiring level 336. The seed layer deposition 332 can include, for example, Titanium (Ti) and Copper (Cu). Technical benefits include those discussed above with improved adhesion.

Some embodiments further include barrier metal 344 residing over the seed layer 332, the first layer wiring level 336, the first layer landless via 340, and the first layer wide via 343. The first barrier metal deposition 344 can include one of Nickel (Ni) and Cobalt (Co). Technical benefits include those discussed above with a barrier layer formed of readily available materials.

Some embodiments further include a third layer residing on the second layer; the third layer is configured in accordance with the first layer. Technical benefits include those discussed above while facilitating multiple wiring layers.

Some cases further include an outer Titanium and Copper deposition 348 residing on the second layer, an outer copper plating 352 residing on the outer Titanium and Copper deposition 348 and an outer barrier metal deposition 356 residing on the third copper plating 352. Technical benefits include those discussed above while facilitating connections to above structures.

In some cases, the first layer wide via 343 is entirely recessed within the first layer. Technical benefits include those discussed above while facilitating fabrication.

In another aspect, an exemplary interconnect structure includes a substrate 828; and a first layer including: a first layer wiring level 836 outward of the substrate 828; and a first layer landless via 840 outward of the first layer wiring level 836. A second layer includes a second layer wiring level 836 outward of the first layer landless via 840; second layer landless via 840 outward of the second layer wiring level 836; and a second layer wide via 843 outward of the second layer landless via 340. A dielectric coating 860 fills voids between the substrate 828, the first layer wiring level 836, the first layer landless via 840, the second layer wiring level 836, the second layer landless via 840, and the second layer wide via 843. The second layer wide via is wider than the second layer landless via. Technical benefits include an interconnect structure that increases wiring density per unit length; and an interconnect structure that allows use of a wide range of dielectric materials.

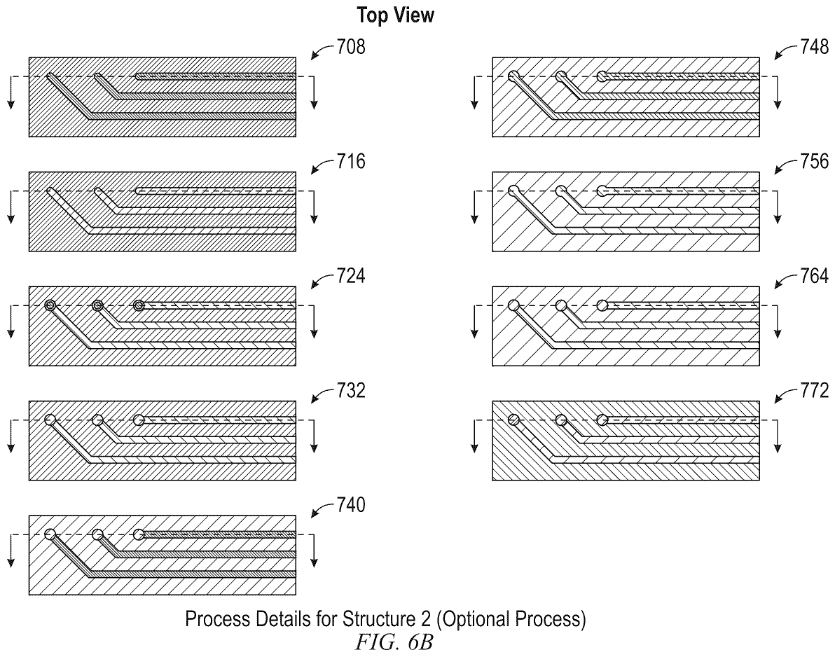

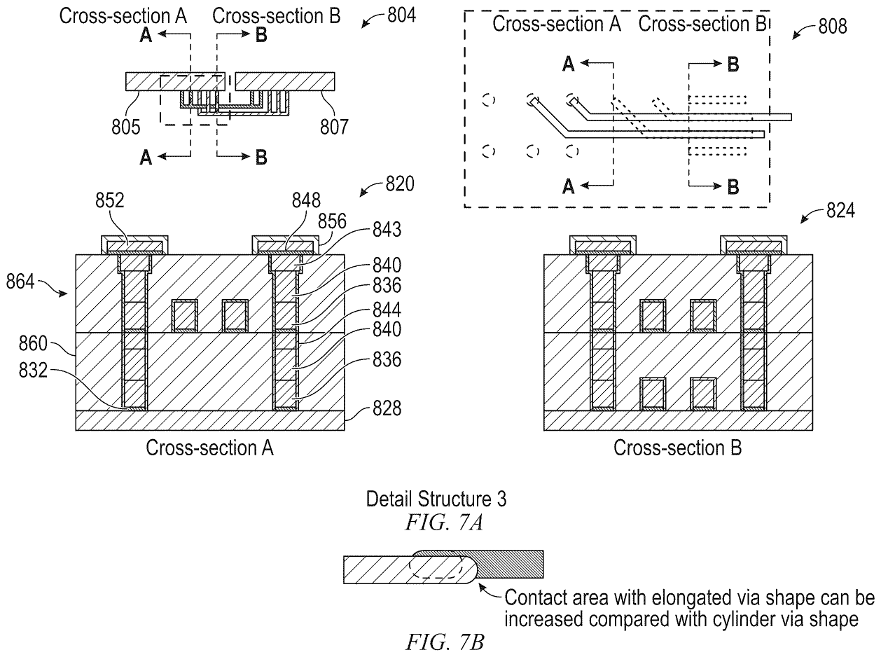

In some cases, the first layer landless via 840 is configured with an elongated shape as shown in FIG. 7B. Technical benefits include those discussed above while maintaining the desired contact area considering misalignment.

In one aspect, an exemplary method includes depositing a seed layer 332 on a substrate 328 (operation 240); applying a first photoresist on the seed layer 332 and patterning the first photoresist (operation 242; cross-sectional view 404; top view 408); plating a first copper plating 336 of a current wiring level (operation 244; cross-sectional view 412; top view 416); applying a second photoresist on the wiring level and patterning the second photoresist (operation 246; cross-sectional view 420; top view 424); plating a second copper plating 340 of a via level, wherein the second copper plating 340 fills recesses of both the first photoresist and the second photoresist (operation 248; cross-sectional view 428; top view 432); stripping the first photoresist and the second photoresist, and etching the seed layer 332 (operation 250; cross-sectional view 436; top view 440); depositing a barrier metal 344 (operation 252; cross-sectional view 444; top view 448); applying and curing a dielectric coating 360 (operation 254; cross-sectional view 452; top view 456); and performing a planarization step to reveal copper/vias (operation 256; cross-sectional view 460; top view 464).

In example embodiments, the depositing of the seed layer 332 (operation 240), the applying of the first photoresist on the seed layer 332 (operation 242; cross-sectional view 404; top view 408), the plating of the first copper plating 336 (operation 244; cross-sectional view 412; top view 416), the applying of the second photoresist (operation 246; cross-sectional view 420; top view 424), the plating of the second copper plating 340 (operation 248; cross-sectional view 428; top view 432), the stripping of the first photoresist and the second photoresist and the etching of the seed layer 332 (operation 250; cross-sectional view 436; top view 440), the depositing of the barrier metal 344 (operation 252; cross-sectional view 444; top view 448), the applying and curing of the dielectric coating 360 (operation 254; cross-sectional view 452, top view 456), and the performing of the planarization step (operation 256; cross-sectional view 460; top view 464) are repeated for each intermediate layer.

Techniques as disclosed herein can provide substantial beneficial technical effects. Some embodiments may not have these potential advantages and these potential advantages are not necessarily required of all embodiments. By way of example only and without limitation, one or more embodiments can provide one or more of:
a semiconductor structure and method that increases wiring density per unit length;
elimination of the need for a dry etch process when fabricating landless wide via structures;
a wider range of dielectric materials that can be selected for fabricating landless wide via structures (for example, non-photosensitive material can be used);
use of wide-vias at different levels (layers) than wiring levels (layers); and
planarization that helps achieve finer line and space (This is a complex problem-as the number of layers increases, the undulation of the dielectric film becomes larger, e.g. a few microns (more than the thickness of wiring). In this case, when performing lithography to form fine resist patterns with a width of 1 μm (e.g.), the focus of the exposure shifts and it becomes impossible to form the minimum pattern with one exposure condition even for the same layer).

One of the challenges for the organic RDL is wiring density where the wiring density depends on a line/space capability as well as via land size. With a semi-additive process, via land size strongly depends on photosensitive dielectric material. In general, a minimum via diameter of photosensitive dielectric material (e.g., Photosensitive Polyimide (PSPI)) is larger than that of photoresist for plating. Also, via shape of the photosensitive dielectric material is typically tapered. Therefore, larger via land size is required, resulting in lower wiring density. It is worth noting that RDL can be fabricated not only on a wafer (either silicon or glass) but also on a panel (e.g. 600 mm×600 mm,), which is larger than a 300 mm wafer. So more parts can be fabricated on a panel than on a wafer.

With dry etching, via diameter and shape can be improved, but it still requires a land for an etch stop, which is larger than the via diameter. Conventional techniques thus include a standard semi-additive via structure with a large land and tapered via shape (with concomitant material dependency) and a smaller land diameter with a straight via formed by dry etching (but where a land is needed as an etch stop). For example, a land with a diameter of 3 μm is used for the via with a diameter of 2 μm. In one or more embodiments, a land with a diameter of 2 μm can be used. On that land, a thin via, which has the same diameter as the land is formed. Above the thin via, a wide via is formed and the wide via can be 3 μm or 2.5 μm etc. depending on alignment accuracy. The land, which exists at the same level as the wiring, can be shrunk, so wiring density can be increased.

### Landless Wide Via Structures for High Density Interconnect

In general, a landless via structure is provided for increasing wiring density with flexibility of dielectric material selection (it is noted that non-photo-sensitive materials can be used). In example embodiments, no dry etch is needed. Some embodiments can be combined with chemical-mechanical planarization (CMP) for finer lines and spacing. In some embodiments, the entirety of the Cu is covered by a barrier. Indeed, in one or more embodiments, a via reveal process is employed. One non-limiting example of a suitable method is CMP. Barrier materials to prevent Cu migration or Cu surface oxidation are employed in one or more embodiments depending on dielectric materials.

### Process Flow

In example embodiments, wiring layer fabrication is performed with a semi-additive process (but without resist stripping). Example embodiments include one or more of:
a second resist layer patterning for a via layer;
Copper plating of a via layer;
resist strip and seed etch;
barrier layer deposition;
dielectric deposition; and
planarization.

These steps can then be repeated to form the next wiring layer, and so on.

### Structure: High Density Interconnects with Bump Pitch Reduction

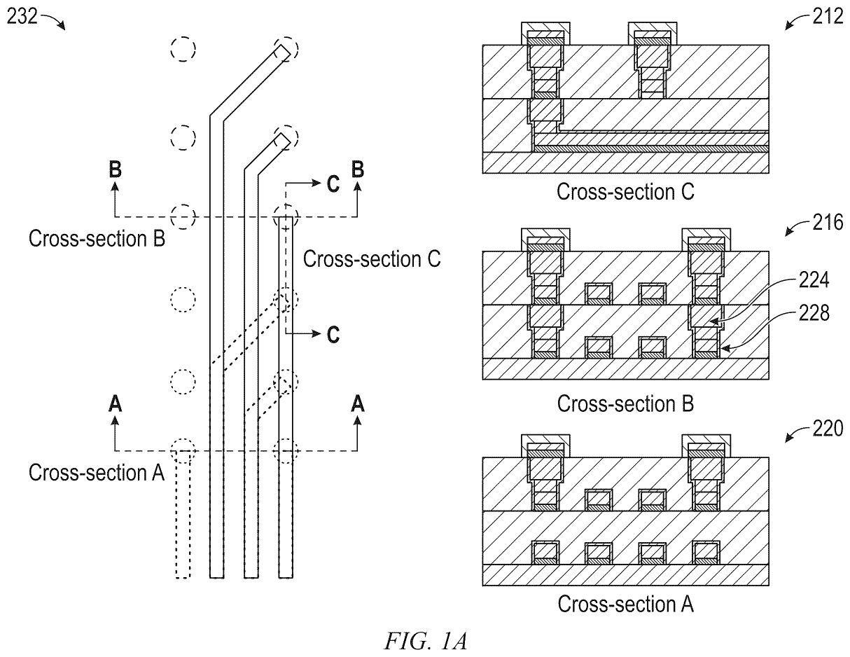

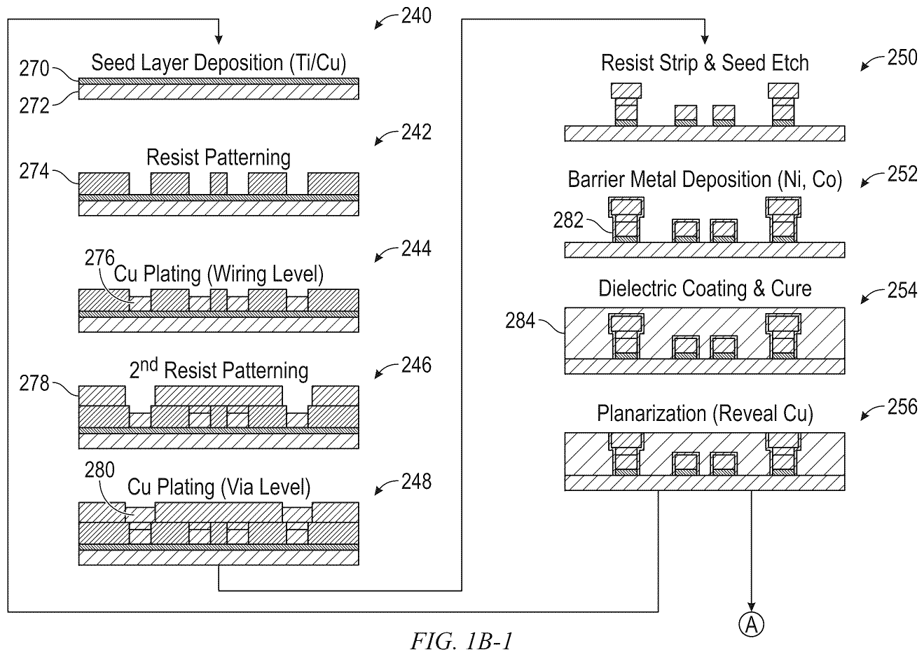

FIG. 1A illustrates cross-sections 212, 216, 220 for example landless via structures, in accordance with example embodiments, taken along lines C, B, and A, respectively, in top view 232. Views 216, 220 are transverse to the metal lines and view 212 is along a metal line. In example embodiments, a method enables the fabrication of such landless via structures for high density interconnects. Example embodiments feature:
via on line and landless via structure 228 (eliminating misalignment);
a wide via structure 224 which is located at the via level (a different level from the wiring level);
Copper surfaces covered by barrier metals;
via lands in wiring levels are not required;
high density wiring; and
conventional via contact diameter.

### Process

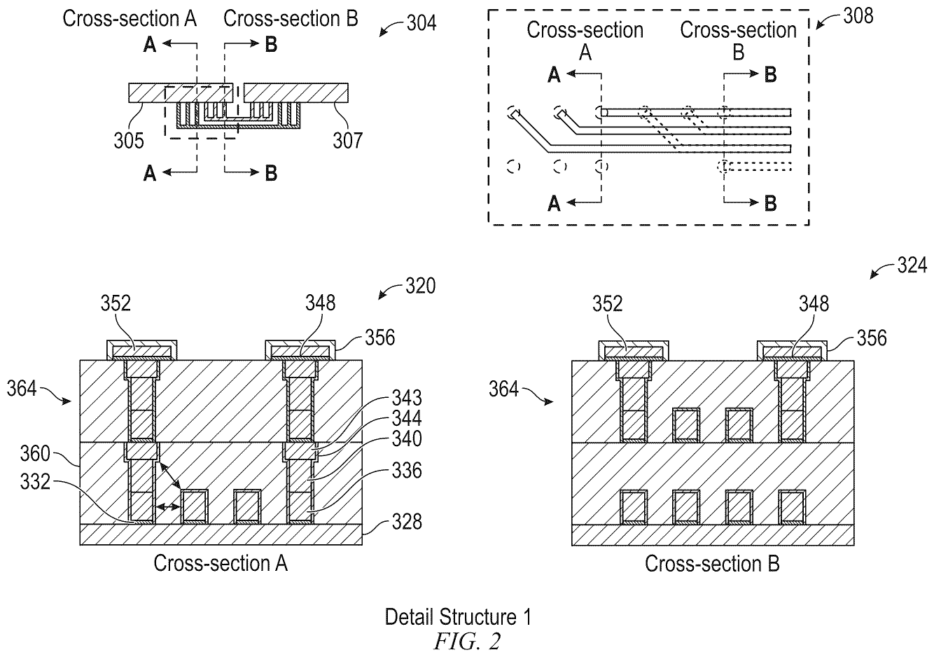

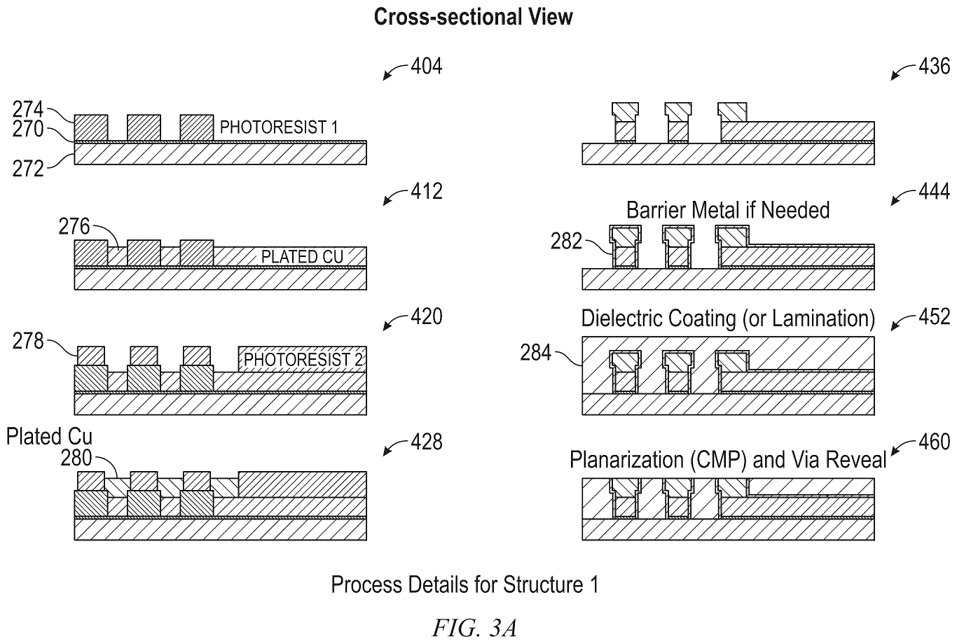

FIG. 1B is an example method for wiring layer fabrication, in accordance with example embodiments. FIG. 3A shows a cross-sectional view along the dotted line in the top view for various steps of the process of FIG. 1B, in accordance with example embodiments. FIG. 3B shows a top view for various steps of the process of FIG. 1B, in accordance with example embodiments. In example embodiments, a seed layer of Titanium (Ti) and Copper (Cu) 270 is deposited on a substrate 272 (operation 240). Generally, the seed layer includes two layers. In one or more embodiments, the bottom layer is titanium to improve adhesion, and the top layer is copper, which is the seed for the next copper electroplating. A first photoresist 274 is applied and patterned using known lithographic techniques (operation 242; cross-sectional view 404; top view 408) followed by a copper plating 276 of the current wiring level (operation 244; cross-sectional view 412; top view 416). A second photoresist 278 is applied and patterned (operation 246; cross-sectional view 420; top view 424) followed by a copper plating 280 of the via level above the current wiring level (operation 248; cross-sectional view 428; top view 432).

The photoresist is stripped and the seed layer is etched (operation 250; cross-sectional view 436; top view 440). Barrier metal 282 (e.g., Nickel (Ni) or Cobalt (Co)) is deposited, as appropriate (operation 252; cross-sectional view 444; top view 448). A dielectric coating 284 is applied and cured (lamination can instead be employed) (see operation 254; cross-sectional view 452; top view 456) and a planarization step (e.g., CMP) is performed to reveal the copper/vias (operation 256; cross-sectional view 460; top view 464). In one or more embodiments, the barrier metal can be Ni or Co; they are alternatives. Either material is satisfactory. The barrier metal can be deposited by electroless plating, for example. An inorganic barrier layer such as SiN or SiO₂ can also be used. Those can be deposited by plasma chemical vapor deposition (CVD), for example.

In one or more embodiments, operations 240-256 are repeated until the last metal layer is ready for fabrication. When the last metal layer is ready for fabrication following operation 256, a seed layer 286 of Titanium (Ti) and Copper (Cu) is deposited (operation 258). Photoresist 288 is applied and patterned (operation 260) followed by a copper plating 290 of the last wiring/metal level (operation 262).

The resist is stripped and the seed layer is etched (operation 264). A barrier metal 292 (e.g., Nickel (Ni), Palladium (Pd), Gold (Au), or the like) is deposited (operation 266).

In alternative embodiments, when the last metal layer is ready for fabrication following operation 256, a barrier metal 294 is deposited (operation 268). In this aspect, the barrier metal 294 can be the same as the barrier metal 292. The barrier metal 294 can be fabricated after the operation 256. The barrier metal 292 and 294 can be changed from Ni/Pd/Au (3 layers) to, for example, Ni/Cu/Solder (Sn, Sn—Ag etc.). In this case, it can be referred to as terminal metal instead of barrier metal.

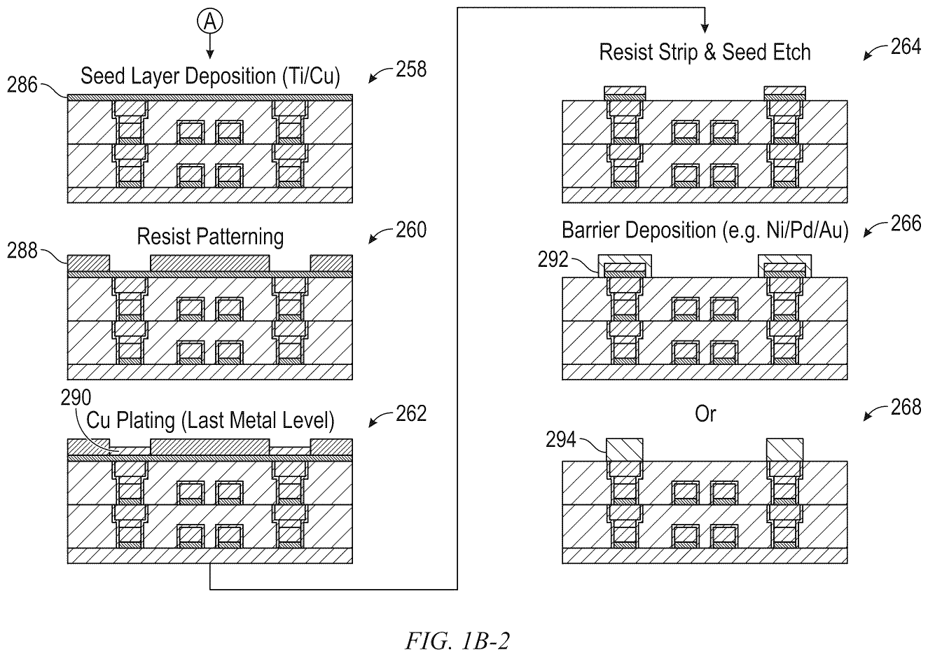

FIG. 2 illustrates detailed cross-sectional views 320, 324 of an example structure produced using the method of FIGS. 1B and 3A-3B, in accordance with example embodiments. Representation 308 is a top view that illustrates the locations of the cross-sectional views 320, 324 within the example structure (the cross section along line A corresponds to view 320 and the cross section along line B corresponds to view 324); representation 304 is a side view of the interconnections between two semiconductor builds 305, 307. As used herein, semiconductor builds include chips, dies, wafers, interposers, or combinations thereof. As illustrated in the cross-sectional view 320, the structure is fabricated with a seed layer deposition of Titanium (Ti) and Copper (Cu) 332 on a substrate 328. A copper plating 336 of a first wiring level resides on the Titanium and Copper 332 and a landless via 340 of a via level resides on the copper plating 336 of the first wiring level. In example embodiments, a wide via 343 is outward of the landless via 340 and a barrier metal 344 as described above resides over the elements 332, 336, 340, 344, as illustrated in FIG. 2. A dielectric coating 360 fills the void between the above structures of the bottom-most and intermediate layers. The above structure is repeated for each intermediate layer 364 of the structure. In example embodiments, the top-most layer may also include Titanium and Copper deposition 348, copper plating 352, and a barrier metal deposition 356.

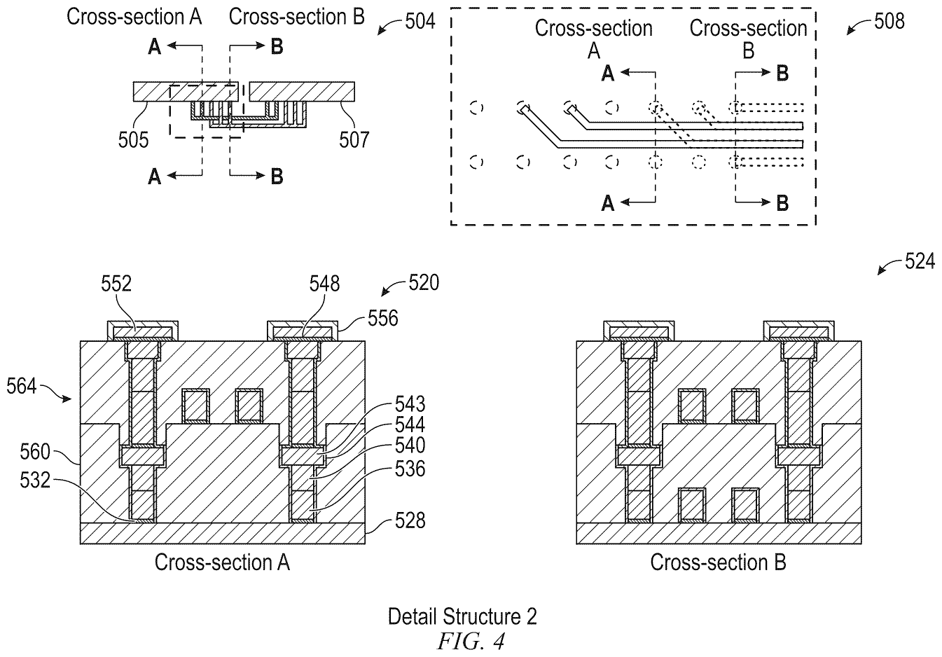

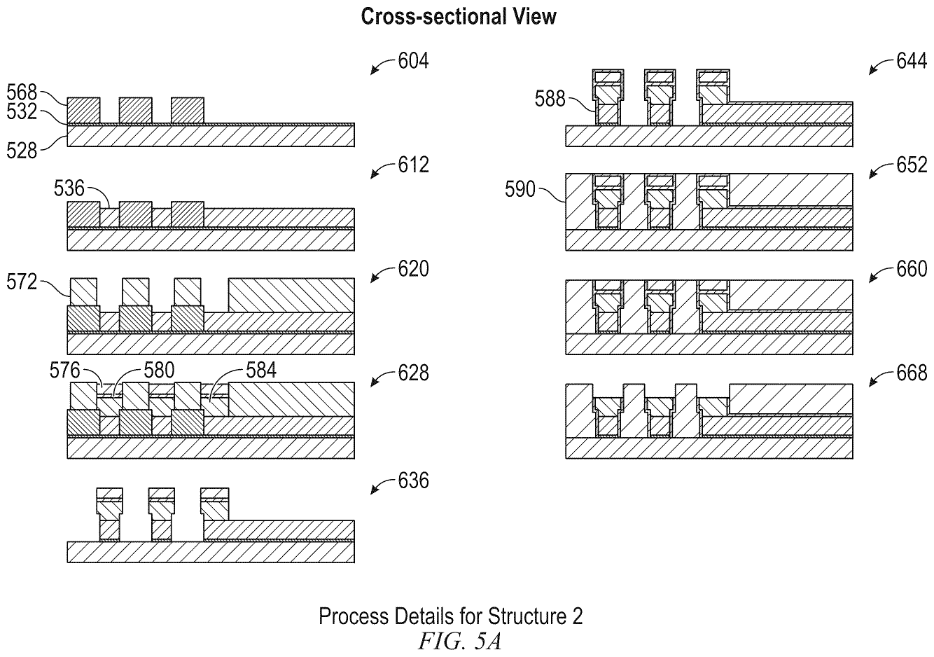

FIG. 5A shows a series of cross-sectional views along the dotted lines in the corresponding top views for various alternative steps of the process of FIG. 1B, in accordance with example embodiments. FIG. 5B shows a top view for various steps of the process of FIG. 1B, in accordance with example embodiments. In example embodiments, a seed layer of Titanium (Ti) and Copper (Cu) 532 is deposited on a substrate 528 (operation 240). A first photoresist 568 is applied and patterned (operation 242; cross-sectional view 604; top view 608) followed by a copper plating 536 of the current wiring level (operation 244; cross-sectional view 612; top view 616). A second photoresist 572 is applied and patterned (operation 246; cross-sectional view 620; top view 624) followed by a copper plating 584, a barrier metal 580 and copper or nickel plating 576 of a via level (operation 248; cross-sectional view 628; top view 632).

The photoresist is stripped and the seed is etched (operation 250; cross-sectional view 636; top view 640). A barrier metal 588 of Nickel (Ni) and Cobalt (Co) is deposited (operation 252; cross-sectional view 644; top view 648). A dielectric coating 590 is applied and cured (operation 254; cross-sectional view 652; top view 656), and a planarization step is performed to reveal the copper/vias (operation 256; cross-sectional view 660; top view 664). Referring to cross section view 668 and top view 672, in some instances, plating layer 576 is etched; then the barrier layer, which is revealed by etching the plating layer 576, is also etched. Etching 576 is optional and layer 576 can remain in some cases.

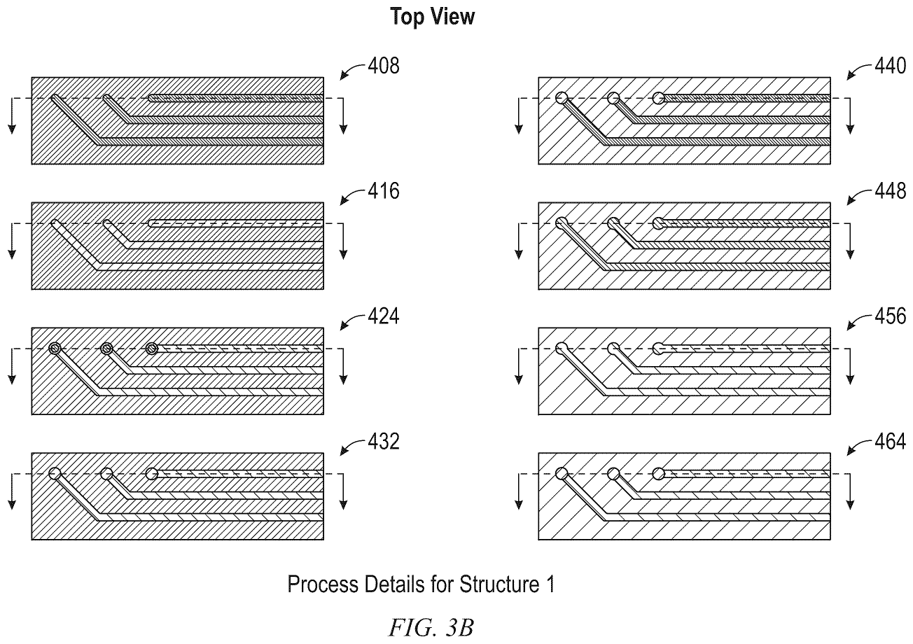

FIG. 4 illustrates a detailed cross-sectional views 520, 524 of an example structure produced using the method of FIGS. 5A-5B, in accordance with example embodiments. Representation 508 is a top view that illustrates the locations of the cross-sectional views 520, 524 within the example structure (the cross section along line A corresponds to view 520 and the cross section along line B corresponds to view 524); representation 504 is a side view of the interconnections between two semiconductor builds 505, 507. This interconnection is used when equal-length wiring is required. As illustrated in the cross-sectional view 520, the structure is fabricated with a seed layer deposition of Titanium (Ti) and Copper (Cu) 532 on a substrate 528. Copper plating 536 of a first wiring level resides on the Titanium (Ti) and Copper (Cu) 532 and a copper plating 540 of a landless via resides on the copper plating 536 of the first wiring level. In example embodiments, a wide via 543 is outward of the landless via 540 and a barrier metal 544 as described above resides over the elements 532, 536, 540, 544, as illustrated in FIG. 4. The above structure is repeated for each intermediate layer 564. A dielectric coating 560 fills the void between the above structures of the bottom-most and intermediate layers. In example embodiments, the top-most layer also includes Titanium and Copper deposition 548, a copper plating 552 and a barrier metal deposition 556.

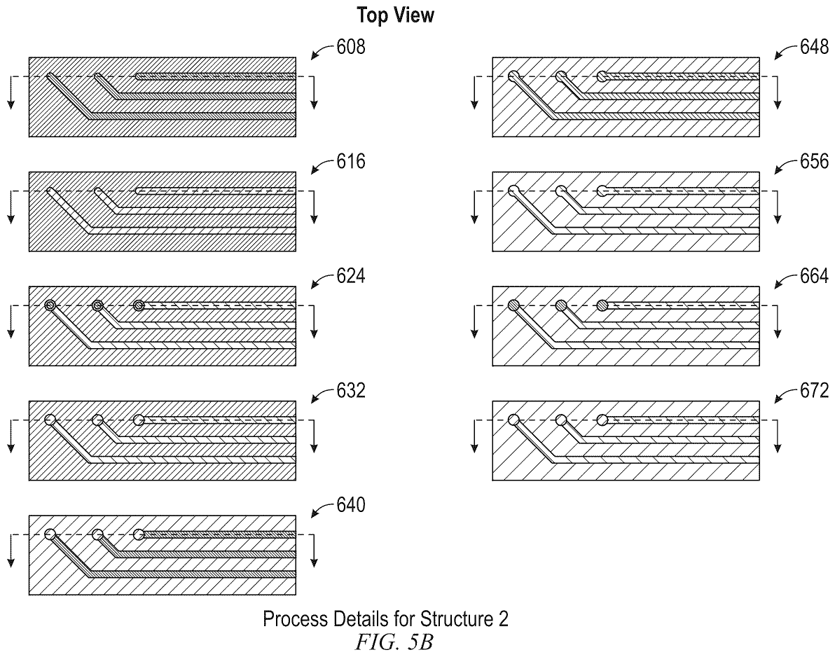

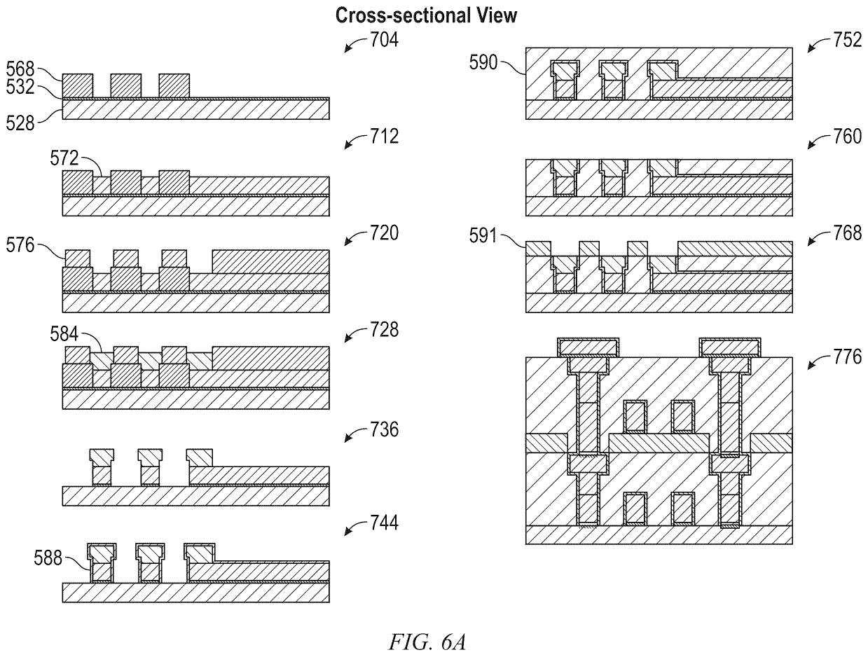

FIG. 6A shows a series of cross-sectional views along the dotted lines in the corresponding top views for various alternative steps of the process of FIG. 1B, in accordance with example embodiments. FIG. 6B shows a top view for various steps of the process of FIG. 1B, in accordance with example embodiments. In example embodiments, a seed layer of Titanium (Ti) and Copper (Cu) 532 is deposited on a substrate 528 (operation 240). A first photoresist 568 is applied and patterned (operation 242; cross-sectional view 704; top view 708) followed by copper plating 572 of the current wiring level (operation 244; cross-sectional view 712; top view 716). A second photoresist 576 is applied and patterned (operation 246; cross-sectional view 720; top view 724) followed by a copper plating 584 of the via level above the current wiring level (operation 248; cross-sectional view 728; top view 732).

The photoresist is stripped and the seed is etched (operation 250; cross-sectional view 736; top view 740). A barrier metal 588 of Nickel (Ni) and Cobalt (Co) is deposited (operation 252; cross-sectional view 744; top view 748). A dielectric coating 590 is applied and cured (operation 254; cross-sectional view 752; top view 756) and a planarization step is performed to reveal the copper/vias (operation 256; cross-sectional view 760; top view 764). Then, referring to view 768 and top view 772, a dielectric coating 591 (different from the dielectric material 590) is applied, patterned, and cured. This dielectric material 591 can be photosensitive and patterned by lithography. This additional dielectric layer increases the distance in the Z direction between the wide via and the wiring in the layer above it, as seen in view 776.

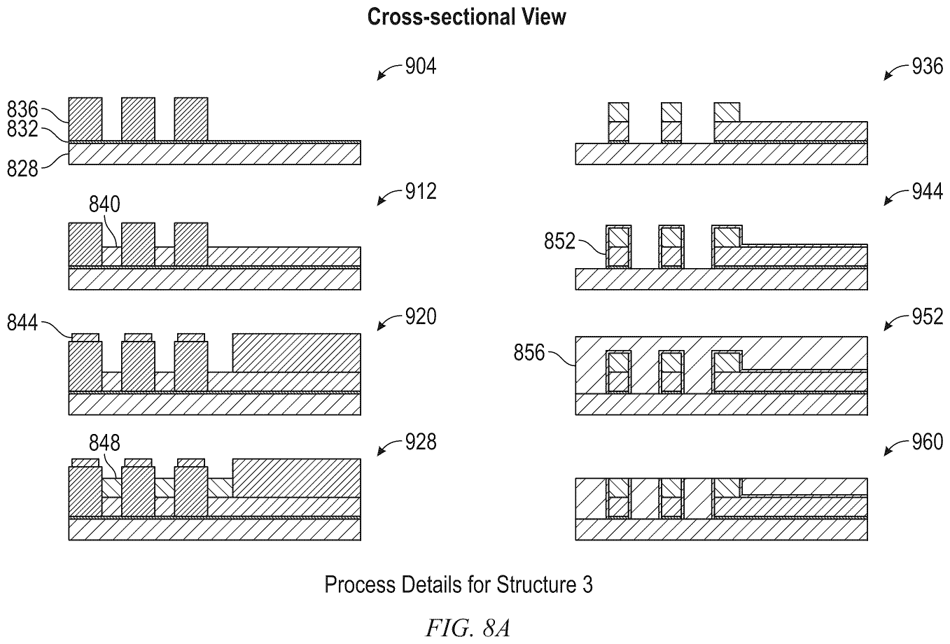

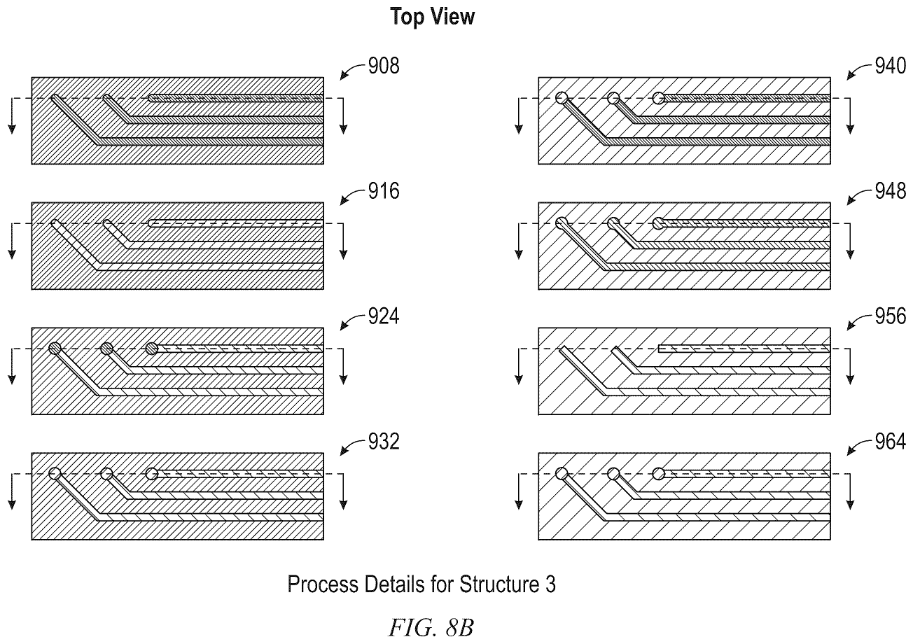

FIG. 7A illustrates detailed cross-sectional views 820, 824 of an example structure produced using the method of FIGS. 8A-8B, in accordance with example embodiments. Representation 808 is a top view that illustrates the locations of the cross-sectional views 820, 824 within the example structure (the cross section along line A corresponds to view 820 and the cross section along line B corresponds to view 824); representation 804 is a side view of the interconnections between two semiconductor builds 805, 807. As illustrated in the cross-sectional view 820, the structure is fabricated with a seed layer deposition of Titanium (Ti) and Copper (Cu) 832 on a substrate 828. A copper plating 836 of a first wiring level resides on the Titanium and Copper 832 and a copper plating 840 of a landless via resides on the copper plating 836 of the first wiring level. In example embodiments taking this approach, a wide via is not employed at this stage and a barrier metal 844 as described above resides over the elements 832, 836, 840 of the via level, as illustrated in FIG. 7A. A dielectric coating 860 fills the void between the above structures of the bottom-most and intermediate layers 864. The above structure is repeated for each intermediate layer 864. In example embodiments, the top-most layer also includes Titanium and Copper deposition 848, a copper plating 852 and a barrier metal deposition 856. In the example in FIG. 7A, only the outermost layer has a wide via 843.

FIG. 7B illustrates an elongated via shape with a contact area that is increased compared with a cylinder via shape, in accordance with example embodiments. Misalignment can affect contact area between the wiring and the via. The misalignment causes contact area reduction (i.e. resistance increase). An elongated via shape as depicted in FIG. 7B can be used to maintain the desired contact area considering misalignment. The elongated shape is elongated into the page in FIG. 7A.

FIG. 8A shows a series of cross-sectional views along the dotted lines in the corresponding top views for various steps of the process of FIG. 1B, in accordance with example embodiments. FIG. 8B shows a top view for various steps of the process of FIG. 1B, in accordance with example embodiments. In example embodiments, a seed layer of Titanium (Ti) and Copper (Cu) 832 is deposited on a substrate 828 (operation 240). A first photoresist 836 is applied and patterned (operation 242; cross-sectional view 904; top view 908) followed by a copper plating 840 of the current wiring level (operation 244; cross-sectional view 912; top view 916). A second photoresist 844 is applied and patterned (operation 246; cross-sectional view 920; top view 924) followed by a copper plating 848 of the via level above the current wiring level (operation 248; cross-sectional view 928; top view 932).

The resist is stripped and the seed is etched (operation 250; cross-sectional view 936; top view 940). A barrier metal 852 of Nickel (Ni) and Cobalt (Co) is deposited (operation 252; cross-sectional view 944; top view 948). A dielectric coating 856 is applied and cured (operation 254; cross-sectional view 952; top view 956) and a planarization step is performed to reveal the copper/vias (operation 256; cross-sectional view 960; top view 964). Steps from 904 to 960 are repeated as appropriate for inner layers. For the most outer layer, steps from 258 to 268 are performed.

It is noted that the land diameter in the dry etching process and the wide-via diameter in example embodiments are determined in consideration of lithography alignment and diameter variations. Therefore, there is not a large difference between the land diameter and the wide via diameter in one or more exemplary embodiments. In the case of a dry etching process, however, the land diameter must typically be larger considering its role as a dry etching stopper, and the lands exist on the same level as wiring, disadvantageously resulting in reduced space for wiring.

In the example embodiments of FIGS. 7A, 7B, 8A, and 8B, misalignment potentially affects the contact area between the wiring and the via. An elongated via shape as discussed with respect to FIG. 7B can be used to maintain an appropriate contact area considering misalignment; such an elongated shape can be achieved by adapting known photolithography and etching techniques as would be apparent to the skilled artisan given the teachings herein. For other embodiments utilizing wide vias, the wide vias address misalignment and size variation, and do not need to have the elongated via shape of FIG. 7B.

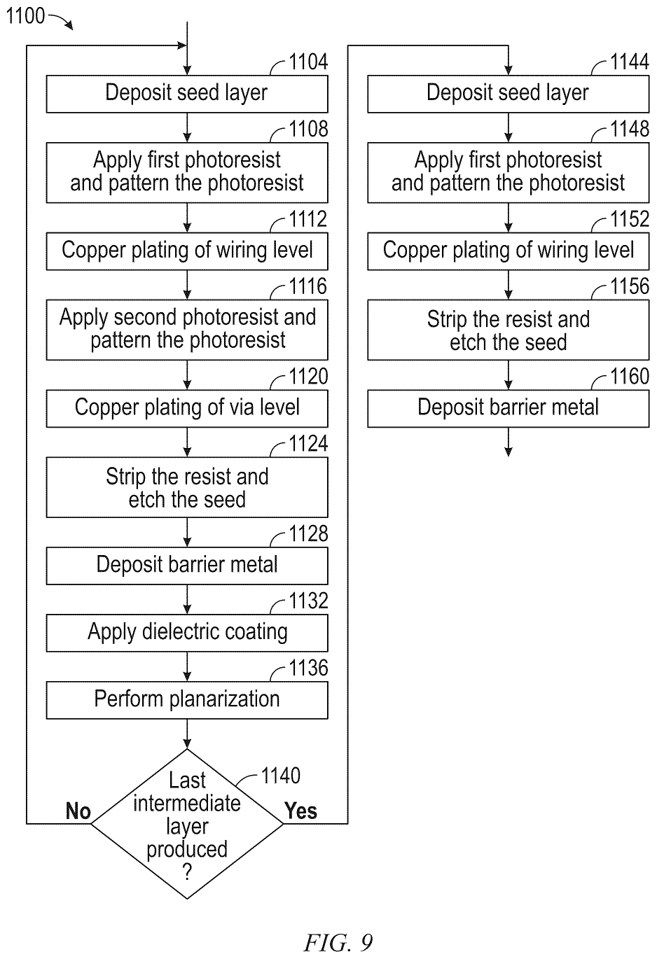

FIG. 9 is a flowchart 1100 for the example method for wiring layer fabrication, in accordance with example embodiments. In example embodiments, a seed layer of Titanium (Ti) and Copper (Cu) is deposited (operation 1104). A first photoresist is applied and patterned (operation 1108) followed by a copper plating of the current wiring level (operation 1112). A second photoresist is applied and patterned (operation 1116) followed by a copper plating of a via level above the current wiring level (operation 1120).

The resist is stripped and the seed layer is etched (operation 1124). A barrier metal of Nickel (Ni) and Cobalt (Co) is deposited (operation 1128). A dielectric coating is applied and cured (operation 1132) and a planarization step is performed to reveal the copper/vias (operation 1136).

Operations 1104-1132 are repeated until the last metal layer is ready for fabrication. In example embodiments, a check is performed to determine if the last intermediate level has been produced (decision block 1140). If the last intermediate level has not been produced (NO branch of decision block 1140), the method proceeds with operation 1104; otherwise (YES branch of decision block 1140), a seed layer of Titanium (Ti) and Copper (Cu) is deposited (operation 1144). A first photoresist (i.e., first at this stage) is applied and patterned (operation 1148) followed by a copper plating of the last wiring/metal level (operation 1152). The resist is stripped and the seed layer is etched (operation 1156). A barrier metal of Nickel (Ni), Palladium (Pd) and Gold (Au) is deposited (operation 1160). Other materials can be used in other embodiments of fabrication methods.

The drawing figures as discussed above depict exemplary processing steps/stages in the fabrication of exemplary structures. Although the overall fabrication methods and the structures formed thereby are entirely novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example James D. Plummer et al., Silicon VLSI Technology: Fundamentals, Practice, and Modeling 1^{st} Edition, Prentice Hall, 2001, which is hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices or other layers may not be explicitly shown in a given figure for ease of explanation. This does not imply that the semiconductor layer(s) or other layer(s) not explicitly shown are omitted in the actual integrated circuit device.

At least a portion of the techniques described above may be implemented in an integrated circuit. In forming integrated circuits, identical dies are typically fabricated in a repeated pattern on a surface of a semiconductor wafer. Each die includes a device described herein, and may include other structures and/or circuits. The individual dies are cut or diced from the wafer, then packaged as an integrated circuit. One skilled in the art would know how to dice wafers and package die to produce integrated circuits.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having structures including interconnect layers and associated structures formed in accordance with one or more of the exemplary embodiments.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this invention. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments may be referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “above” and “below”, “top” and “bottom”, and “vertical” are used to indicate relative positioning of elements or structures to each other as opposed to relative elevation.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.72(b). It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. An interconnect structure comprising:
a substrate;
a first layer comprising:
a first layer wiring level outward of the substrate;
a first layer landless via outward of the first layer wiring level; and
a first layer wide via outward of the first layer landless via, the first layer wide via being wider than the first layer landless via; and
a second layer comprising:
a second layer wiring level outward of the first layer wide via;
a second layer landless via outward of the second layer wiring level; and
a second layer wide via outward of the second layer landless via, the second layer wide via being wider than the second layer landless via; and
a dielectric coating filling voids between the substrate, the first layer wiring level, the first layer landless via, the first layer wide via, the second layer wiring level, the second layer landless via, and the second layer wide via.

2. The interconnect structure of claim 1, further comprising a seed layer between the substrate and the first layer wiring level.

3. The interconnect structure of claim 2, further comprising barrier metal residing over the seed layer, the first layer wiring level, the first layer landless via, and the first layer wide via.

4. The interconnect structure of claim 3, wherein the seed layer comprises Titanium (Ti) and Copper (Cu).

5. The interconnect structure of claim 4, wherein the barrier metal comprises one of Nickel (Ni) and Cobalt (Co).

6. The interconnect structure of claim 1, further comprising a third layer residing on the second layer, the third layer configured in accordance with the first layer.

7. The interconnect structure of claim 1, further comprising an outer Titanium and Copper deposition residing on the second layer, an outer copper plating residing on the outer Titanium and Copper deposition and an outer barrier metal deposition residing on the third copper plating.

8. The interconnect structure of claim 1, wherein the first layer wide via is entirely recessed within the first layer.

9. An assembly comprising:
a first semiconductor build;
a second semiconductor build; and
an interconnect structure joining the first and second semiconductor builds, the interconnect structure comprising:
a substrate;
a first layer comprising:
a first layer wiring level outward of the substrate;
a first layer landless via outward of the first layer wiring level; and
a first layer wide via outward of the first layer landless via, the first layer wide via being wider than the first layer landless via; and
a second layer comprising:
a second layer wiring level outward of the first layer wide via;
a second layer landless via outward of the second layer wiring level; and
a second layer wide via outward of the second layer landless via, the second layer wide via being wider than the second layer landless via; and
a dielectric coating filling voids between the substrate, the first layer wiring level, the first layer landless via, the first layer wide via, the second layer wiring level, the second layer landless via, and the second layer wide via;
wherein the first and second semiconductor builds are electrically coupled using at least a portion of the first layer wiring level, the first layer landless via, the first layer wide via, the second layer wiring level, the second layer landless via, and the second layer wide via.

10. The assembly of claim 9, further comprising a seed layer between the substrate and the first layer wiring level.

11. The assembly of claim 10, further comprising barrier metal residing over the seed layer, the first layer wiring level, the first layer landless via, and the first layer wide via.

12. The assembly of claim 11, wherein the seed layer comprises Titanium (Ti) and Copper (Cu).

13. The assembly of claim 12, wherein the barrier metal comprises one of Nickel (Ni) and Cobalt (Co).

14. The assembly of claim 9, further comprising a third layer residing on the second layer, the third layer configured in accordance with the first layer.

15. The assembly of claim 9, further comprising an outer Titanium and Copper deposition residing on the second layer, an outer copper plating residing on the outer Titanium and Copper deposition and an outer barrier metal deposition residing on the third copper plating.

16. The assembly of claim 9, wherein the first layer wide via is entirely recessed within the first layer.

17. An interconnect structure comprising:
a substrate;
a first layer comprising:
a first layer wiring level outward of the substrate; and
a first layer landless via outward of the first layer wiring level; and
a second layer comprising:
a second layer wiring level outward of the first layer landless via;
a second layer landless via outward of the second layer wiring level; and
a second layer wide via outward of the second layer landless via, the second layer wide via being wider than the second layer landless via; and
a dielectric coating filling voids between the substrate, the first layer wiring level, the first layer landless via, the second layer wiring level, the second layer landless via, and the second layer wide via.

18. The interconnect structure of claim 17, wherein the first layer landless via is configured with an elongated shape.
